(19) United States
(12) Patent Application Publication
(10) Pub. No.: US 2007/0241392 A1
(43) Pub. Date: Oct. 18, 2007

(54) Non-volatile flash memory structure and method for operating the same

(76) Inventors: Hsin-Chang Lin, Chu-pei City (TW); Wen-Chien Huang, Chu-pei City (TW); Ming-Tsang Yang, Chu-pei City (TW); Hao-Cheng Chang, Chu-pei City (TW); Cheng-Ying Wu, Chu-pei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/403,862

(22) Filed: Apr. 14, 2006

(51) Int. Cl. H01L 29/788

(52) U.S. Cl. 257/316

(57) ABSTRACT

A non-volatile memory structure and a method for operating the same are proposed. The non-volatile memory structure makes use of a single floating gate structure and a capacitor structure including a pair of regions doped with different type impurities to increase the capacitance and shrink the area. When performing programming operations to this memory structure, a voltage is applied to the source or a back bias is applied to the substrate of the transistor to greatly reduce the current requirement of a single-gate EEPROM device. When performing erase operations, the drain voltage is raised, and a small voltage is added to the gate to increase the F-N tunneling current, thereby accomplishing the effect of fast erase.

### FIELD OF THE INVENTION

The present invention relates to the structure of a non-volatile memory and a method for operating the same and, more particularly, to the structure of a high capacitance ratio single-gate flash memory and a method for operating the same.

### BACKGROUND OF THE INVENTION

Memory devices can generally be classified into two categories: volatile memories and non-volatile memories. Data in volatile memories can only be kept through continual supply of power. On the contrary, data in non-volatile memories can be maintained for a very long time even if the power is cut off. Exemplified with memories used in computers, DRAMs and SRAMs are volatile memories, while ROMs are non-volatile memories.

Among various kinds of non-volatile memories, electrically erasable programmable read only memories (EEPROMs) have been widely used in electronic products because they have the non-volatile memory function of electrically writing and erasing data and data stored therein won't disappear after the power is cut off.

The programming operation of programmable non-volatile memories is described below. Electric charges are stored to change the gate voltages of memory transistors, or electric charges are not stored to keep the original gate voltages of the memory transistors. The erase operation removes all electric charges stored in the non-volatile memories to restore all non-volatile memories to the original gate voltages of the memory transistors. Therefore, when performing programmable erase to a conventional non-volatile memory, it is necessary to provide a sufficient large voltage to the drain and the source to finish the above action through the channel formed by this high voltage difference. The prior art single gate EEPROM, however, has a too high operation current. Moreover, because its memory array structure is denser and denser, the channel length is shortened, hence causing each memory to mutually affect one another. Besides, because a higher operation current requires a complicated peripheral circuit design, the above high-voltage operation method will make the complexity of the peripheral circuit higher.

Furthermore, in the erase method of the conventional EEPROM, stored electric charges will move from the floating gate to the transistor to be removed due to the Fowler-Nordheim tunneling (F-N tunneling) effect. Because the structure of a single-gate EEPROM memory cell is a sandwich structure of transistor substrate-floating gate-capacitor substrate, stored electric charges can be released to either direction according to the direction of the applied electric field, hence more deteriorating the problem of over erase of the single-gate EEPROM.

Accordingly, the present invention aims to propose a non-volatile memory structure and a method for operating the same to effectively solve the above problems in the prior art.

### SUMMARY OF THE INVENTION

An object of the present invention is to provide a non-volatile memory structure, which makes use of a single floating gate structure and a capacitor structure including a pair of regions doped with different type impurities to increase the capacitance and shrink the area. When performing programming operations, a voltage is applied to the source or a back bias is applied to the substrate of the transistor to greatly reduce the current requirement of a single-gate EEPROM device.

Another object of the present invention is to provide a non-volatile memory structure, which makes use of a single floating gate structure and a capacitor structure including a pair of regions doped with different type impurities, whereby when performing erase operations, the drain voltage is raised, and a small voltage is added to the gate to increase the F-N tunneling current, thereby accomplishing the effect of fast erase.

According to the present invention, a non-volatile memory structure comprises a semiconductor substrate, a transistor structure and a capacitor structure. The transistor structure and the capacitor structure are isolated from each other and located on the semiconductor substrate. The transistor structure comprises a plurality of impurity-doped regions as a source and a drain. The capacitor structure has an N-well located in the semiconductor substrate. A pair of regions doped with different type impurities are disposed in the N-well. A first dielectric is disposed on the surface of the N-well. A first conducting gate is disposed on the first dielectric. The transistor structure and the capacitor structure are electrically connected together as a single floating gate.

The present invention also provides a method for operating a non-volatile memory structure. The method comprises the following steps: applying a substrate voltage, a source voltage, a drain voltage and a control gate voltage to the semiconductor substrate, the source, the drain and the two regions doped with different type impurities, respectively; performing a programming step to make the source voltage larger than the substrate voltage so as to generate a wider depleted source-substrate junction; and performing an erase step to make the control gate voltage larger than the source voltage so as to increase the F-N tunneling current.

The various objects and advantages of the present invention will be more readily understood from the following detailed description when read in conjunction with the appended drawings, in which:

### BRIEF DESCRIPTION OF THE DRAWINGS

FIG. 1 is a cross-sectional view of a non-volatile memory structure of the present invention;

FIG. 2 is a cross-sectional view of a non-volatile memory structure of the present invention having four terminals and;

FIG. 3 is an effective circuit diagram of a non-volatile memory structure of the present invention.

### DETAILED DESCRIPTION OF THE PREFERRED EMBODIMENTS

The present invention solves the problems of multiple manufacturing steps, high degree of difficulty in fabrication and high production cost derived from complicated peripheral circuit design required by a higher operation current when fabricating a prior art non-volatile memory structure. The present invention also solves the problems of over erase and slow erase speed of memory structures of this type during the erase operation.

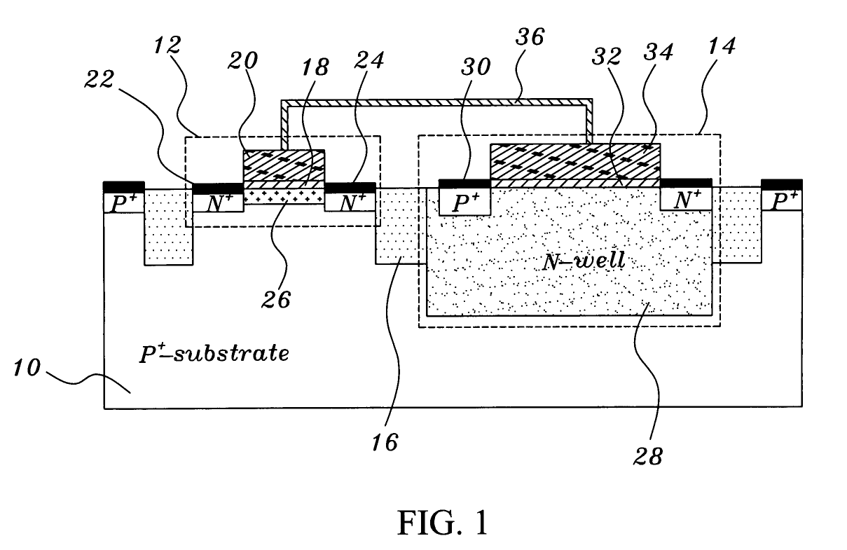

As shown in FIG. 1, a non-volatile memory structure comprises a p-type semiconductor substrate 10. A transistor structure 12 and a capacitor structure 14 that are isolated from each other are disposed on the semiconductor substrate 10. The transistor structure 12 and the capacitor structure 14 are isolated during the standard isolation process. This isolation process utilizes an isolator 16 to isolate the transistor structure 12 from the capacitor structure 14.

This transistor structure 12 is a MOSFET structure. This transistor structure 12 comprises a dielectric 18 and a conducting gate 20. The dielectric 18 is located on the surface of the semiconductor substrate 10. The conducting gate 20 is disposed on the dielectric 18. N⁺-doped regions are ion-implanted in the semiconductor substrate 10 and around the dielectric 18 to be used as a source 22 and a drain 24, respectively. A channel 26 is formed between the source 22 and the drain 24 by means of ion implantation. Besides, the type of impurities doped in the semiconductor substrate 10 differs from that of the impurity-doped regions. For example, in this embodiment, the semiconductor substrate is p-type, while the impurity-doped regions are N⁺-type.

The capacitor structure 14 comprises an N-well 28 located in the semiconductor substrate 10. A pair of regions doped with different type impurities are disposed in this N-well 28. The two regions are an N⁺-type region and a P⁺-type region. A dielectric 32 is disposed on the surface of the N-well 28. A conducting gate 34 is disposed on the dielectric 32 to form a top plate-dielectric-bottom plate capacitor structure 14. Next, poly-silicon is deposited and photolithography is performed to electrically connect the conducting gate 20 of the transistor structure 12 and the top conducting gate 34 of the capacitor structure 14, thereby forming a poly-silicon single floating gate 36. Subsequently, ion implantation is performed to form a control gate. After metallization, the fabrication of a plurality of non-volatile memory structures is finished. Therefore, this non-volatile memory has four terminals, i.e., four connection structures of the source, the drain, the control gate and the substrate. These four terminals can be used for inputting voltage during operation.

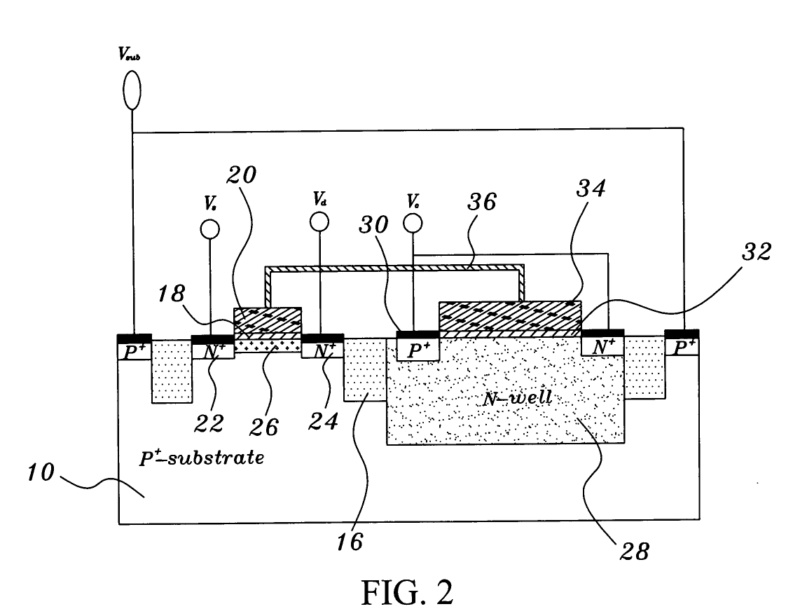

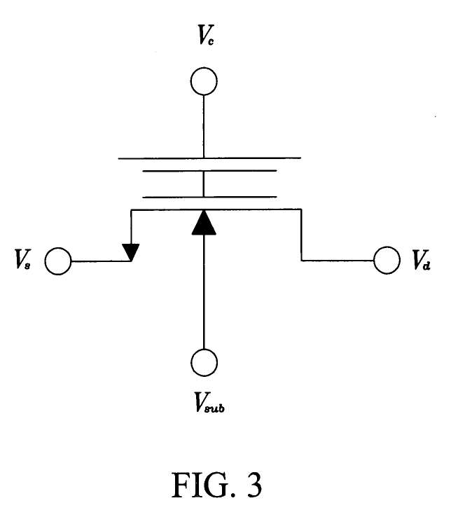

A method for operating the above non-volatile memory structure will be illustrated below. As shown in FIG. 2, a substrate voltage Vsub, a source voltage Vs, a drain voltage Vd and a control gate voltage Vc are first applied to the semiconductor substrate 10, the source 22, the drain 24 and the two regions 30 doped with different type impurities, respectively. FIG. 3 is an effective circuit diagram of a non-volatile memory structure of the present invention.

performing a programming step to make the source voltage larger than the substrate voltage so as to generate a wider depleted source-substrate junction; and performing an erase step to make the control gate voltage larger than the source voltage so as to increase the F-N tunneling current. An ultra-low-current programming condition of this non-volatile memory structure is as follows:

(1) Programming of this non-volatile memory (writing):

a. Let the substrate voltage Vsub be ground (Vsub=0); and

b. Let Vₛ>Vsub=0 and let Vd>Vs>0, Vc>Vs>0.

When Vs>Vsub, a wider depleted source-substrate junction can be formed to improve the efficiency of current flow toward the single floating gate 40, thereby greatly reducing the current requirement of programming a single gate EEPROM device.

There are many ways of letting Vs>Vsub. One way is to extra apply a. nontrivial voltage to the source voltage Vs. Another way is to extra add a back-bias to the substrate voltage Vsub.

(2) Erase of this non-volatile memory:

a. Let the substrate voltage Vsub be ground (Vsub=0); and

b. Let Vc>Vs and let Vd>Vc>Vs>0.

One way of letting Vc>Vs is to extra apply a small voltage to Vc.

When Vc>Vs, the F-N tunneling current can be increased for erase to accomplish the effect of fast erase.

To sum up, the present invention makes use of a single floating gate structure and a capacitor structure including a pair of regions doped with different type impurities to increase the capacitance and shrink the area. When performing programming operations, a voltage is applied to the source or a back bias is applied to the substrate of the transistor to greatly reduce the current requirement of a single-gate EEPROM device. When performing erase operations, the drain voltage is raised, and a small voltage is applied to the gate to increase the F-N tunneling current during erase, thereby accomplishing the effect of fast erase.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A non-volatile memory structure comprising:
a semiconductor substrate;
a transistor structure located on said semiconductor substrate; and
a capacitor structure located on said semiconductor substrate, said capacitor structure having an N-well located in said semiconductor substrate, a pair of regions doped with different type impurities being disposed in said N-well, a first dielectric being disposed on a surface of said N-well, a first conducting gate being disposed on said first dielectric, said transistor structure and said capacitor structure being isolated and electrically connected together as a single floating gate.

2. The non-volatile memory structure as claimed in claim 1, wherein said semiconductor substrate is a p-type semiconductor substrate.

3. The non-volatile memory structure as claimed in claim 1, wherein said two regions doped with different type impurities are an N⁺-type region and a P⁺-type region.

4. The non-volatile memory structure as claimed in claim 1, wherein said transistor structure comprises a second dielectric and a second conducting gate, said second dielectric is located on a surface of said semiconductor substrate, said second conducting gate is disposed on said second dielectric, and impurity-doped regions are disposed in said semiconductor substrate and around said second dielectric to be used as a source and a drain, respectively.

5. The non-volatile memory structure as claimed in claim 4, wherein the type of impurity doped in said semiconductor substrate differs from that of said impurity-doped regions.

6. The non-volatile memory structure as claimed in claim 4, wherein the electric connection between said transistor structure and said capacitor structure is accomplished by connecting said first conducting gate and said second conducting gate to be used as a single floating gate.

7. The non-volatile memory structure as claimed in claim 4, wherein said transistor structure and said capacitor structure are isolated by at least an isolator.

8. The non-volatile memory structure as claimed in claim 1, wherein said transistor is a MOSFET.

9. A method for operating a non-volatile memory, said non-volatile memory comprising a transistor structure and a capacitor structure that are isolated from each other on a semiconductor substrate, said transistor structure comprising impurity-doped regions used as a source and a drain, said capacitor structure comprising a pair of regions doped with different type impurities in an N-well, a first dielectric and a first conducting gate being disposed in order on a surface of said N-well, said transistor structure and said capacitor structure being electrically connected together to be used as a single floating gate, said method comprising:
applying a substrate voltage, a source voltage, a drain voltage and a control gate voltage to said semiconductor substrate, said source, said drain and said two regions doped with different type impurities, respectively;
performing a programming step to make said source voltage larger than said substrate voltage so as to generate a wider depleted source-substrate junction; and
performing an erase step to make said control gate voltage larger than said source voltage so as to increase the F-N tunneling current.

10. The method for operating a non-volatile memory as claimed in claim 9, wherein said two regions doped with different type impurities are an N⁺-type region and a P⁺-type region.

11. The method for operating a non-volatile memory as claimed in claim 9, wherein in said programming step, a back bias can be extra added to said substrate voltage to make said source voltage larger than said substrate voltage.

12. The method for operating a non-volatile memory as claimed in claim 9, wherein in said programming step, a non-trivial voltage can be extra added to said source voltage to make said source voltage larger than said substrate voltage.

13. The method for operating a non-volatile memory as claimed in claim 9, wherein in said erase step, a small voltage can be extra added to said control gate voltage to make said control gate voltage larger than said source voltage.
